(19) United States
(12) Patent Application Publication
(10) Pub. No.: US 2009/0278140 A1
(43) Pub. Date: Nov. 12, 2009

(54) MANUFACTURING METHOD OF SEMICONDUCTOR DEVICE

(75) Inventors: SHIH CHENG HUANG, HSINCHU CITY (TW); PO MIN TU, CHIAYI COUNTY (TW); SHIH HSIUNG CHAN, HSINCHU COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: ADVANCED OPTOELECTRONIC TECHNOLOGY INC., HSINCHU COUNTY (TW)

(21) Appl. No.: 12/433,179

(22) Filed: Apr. 30, 2009

(30) Foreign Application Priority Data
May 9, 2008 (TW) 097117100

(51) Int. Cl. H01L 33/00; H01L 21/20

(52) U.S. Cl. 257/88; 438/39; 257/E33.023; 257/E33.006; 257/E21.09

(57) ABSTRACT

A manufacturing method of a semiconductor device comprises the steps of: providing a substrate; forming a plurality of grooves on the substrate by photolithograph etching or laser engraving, wherein the plurality of grooves divides a surface of the substrate into a plurality of mesas and the substrate is a patterned substrate; and growing a semiconductor device (e.g. photo-electronic device or LED) on the patterned substrate. The semiconductor device comprises at least one layer, wherein the layer directly disposed on the patterned substrate is the first layer. The first layer comprises a plurality of separated regions divided by the grooves.

### BACKGROUND OF THE INVENTION

1. Field of the Invention

The present invention relates to a manufacturing method of a semiconductor device, and relates more particularly to a manufacturing method of a semiconductor device for resolving the issue of internal stresses in layers.

2. Description of the Related Art

From 1950 to the present, light emitting diode (LED) technology has been continuously developed due to its advantages of long working life, small volume, low heat, energy efficiency, high response, mercury-free construction (and other environmental benefits) and monochromatic light. In recent years, LEDs have been widely applied to all kinds of commercial electronic appliances and instruments. For example, computer peripherals, clock indicators, advertising boards, traffic lights, communication appliances and other consumer electronic appliances utilize LEDs in various applications. Particularly, after blue LEDs were introduced to the public, the red, green, and blue LEDs (three color LEDs) were successfully and sequentially developed. These LEDs can be combined to obtain a full color lighting set so that the LEDs can be used in full color display applications.

The current blue LEDs are classified in two groups based on their manufacturing process. One group utilizes a sapphire substrate or an SiC substrate as the base of the LED. The LED with a sapphire base is superior to the LED with an SiC base in physical characteristics, such as brightness and contrast, and electrical characteristics, such as electrical conductivity. Therefore, the sapphire-based LED has better potential for future development.

In the prior arts, a GaN compound semiconductor material is grown on the sapphire substrate. The lattice mismatch between the lattice coefficient of the sapphire and that of the GaN compound is greater than 13%. During epitaxial processes, such lattice mismatch can degrade the quality of the layer grown on the sapphire substrate, and the stress resulting from the lattice mismatch further causes layer defects, including layer cracking. Such cracks on the layers seriously affect the integrity of sequential layers. Therefore, the reliability of the LEDs is degenerated.

In the general prior arts, a multi-layer or a buffer layer is further interposed between two layers having obvious lattice mismatch. However, such a multi-layer or a buffer layer is likely to absorb light so the photo-electronic effect is reduced. Furthermore, the stability and consistency of the epitaxial processes may be reduced. The presence of layers with defects can easily cause the whole LED to be disqualified. The mechanical and electrical characteristics of the stacked layers are also reduced.

U.S. Pat. No. 7,015,511 puts forth the formation of AlGaN on the surface of a discontinuously island-like GaN structure, as shown in FIG. 1. Such a structure prevents the occurrence of cracks. The rules employed in the prior art are as follows: the tensile stresses of material helps cracks to propagate along the inclined planes of island-like GaN structure rather than along a plane parallel to the plane of the AlGaN layer. Therefore, the tensile stresses are increased by the increased thickness of the AlGaN, but the sum of the tensile stresses is not proportional to the increase of the tensile stresses. Even though the discontinuously island-like GaN structure proposed by the prior art resolves the tensile stress problem in the lattice of the material, it does not address the cause of the problem because the tensile stresses still exist in the layers and cannot be released. If the height of the grown AlGaN layer is over that of the islands, the inclined planes of the islands are overlaid by the AlGaN material. Therefore, the island-like GaN structure is filled and leveled up by the AlGaN material. When the inclined planes disappear, the crack problem reoccurs. In view of the aforesaid, the poor stability and consistency of the epitaxial processes of the discontinuously island-like structure are unfavorable to the mass production of the LEDs.

Therefore, it is necessary to develop a new manufacturing method or a new structure of semiconductor devices to avoid the occurrence of cracks in the devices. Such development should also improve the reliability of the device and reduce the manufacturing cost so as to meet the requirements of the market.

### SUMMARY OF THE INVENTION

The primary aspect of the present invention is to provide a manufacturing method of semiconductor device. The problem of the disqualified layers resulting from lattice mismatch is resolved. In addition, in an LED, the issue of cracks between the interface of a sapphire substrate and a group III Nitride stacked on the substrate can be resolved.

The present invention provides a manufacturing method of a semiconductor device, which comprises the steps of: providing a substrate; forming a plurality of grooves on the substrate by photolithograph etching or laser engraving, wherein the plurality of grooves divides a surface of the substrate into a plurality of mesas and the substrate is a patterned substrate; and growing a semiconductor device (e.g. photo-electronic device or LED) on the patterned substrate. The semiconductor device comprises at least one layer, wherein the layer disposed directly on the patterned substrate is the first layer. The first layer comprises a plurality of separated regions divided by the grooves.

### BRIEF DESCRIPTION OF THE DRAWINGS

The invention will be described according to the appended drawings in which:

FIG. 1 is a schematic diagram of a traditional LED having a GaN layer formed on a sapphire substrate with a discontinuously island-like structure;

FIGS. 2A-2E illustrate the manufacturing processes of the semiconductor device in accordance with the present invention;

FIG. 3A is a solid diagram of the patterned substrate in accordance with the present invention;

FIG. 3B is a cross section diagram of the patterned substrate in accordance with the present invention; and

FIG. 3C is a structure diagram of semiconductor devices in accordance with the present invention.

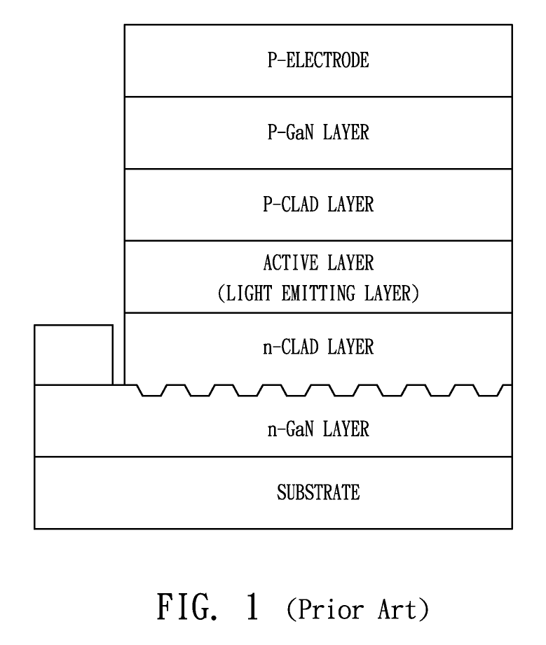

### DETAILED DESCRIPTION OF THE INVENTION

The present invention provides a manufacturing method of a semiconductor device. For complete understanding of the present invention, the following description will describe in detail the manufacturing steps and the composition. The present invention is not limited by the specified particulars of semiconductor device manufacturing that are familiar to a person skilled in the art. In addition, well-known compositions or steps are not described in detail so as to avoid any additional limitation. The preferable embodiments of the present invention are described in detail. In addition to the detailed descriptions, the present invention also can be applied to other embodiments. Therefore, the scope of the present invention is not limited, and is dependent on the following claims.

In general prior arts, a buffer layer or a buffer structure is often interposed between two layers with mismatched lattice coefficients or formed on the surface of the substrate. Disqualifying problems such as cracks and defects resulting from the lattice mismatch are thereby resolved. The following descriptions state the resolving method respectively put forth by two prior arts.

U.S. Pat. No. 7,326,963 puts forth a superlattice structure as a strain-relieving structure to release the stresses resulting from the lattice mismatch between layer materials. However, the superlattice structure is a fine laminated composite material with a specific type. It comprises two kinds of different chemical materials and nanometer-scale layers with different lattices whose scales range from several nanometers to several tens of nanometers in a staggered-laminated manner. The sequence of the superlattice layers should strictly follow a certain periodical rule. Therefore, the quality of the superlattice structure is not easily maintained, and the structure is also difficult to create. The disqualified layers easily reduce the photo-electronic effects of the device.

U.S. Pat. No. 5,874,747 puts forth a method to resolve the problem of lattice dislocation between the layers. This patent teaches that an LED is formed on an SiC substrate with mesa structures. The problem of lattice dislocation due to lattice mismatch (mismatch level around 3%) between the SiC and GaN materials is resolved. The dislocation density of the linear interface can be reduced when small area mesh structures are employed for a GaN series layer. This patent is based on the following rules: the occurrence of dislocations is moved to the tip of the corner of the small area mesh. One dislocation line should meet another dislocation line and the two dislocation lines would then mutually counteract each other.

However, in addition to complicated processes and difficult implementation, the aforesaid resolving methods for smoothing lattice mismatch cannot easily control the yield of the manufacture. The second prior art improves the lattice dislocation when the level of the lattice mismatch is around 3%, but it cannot resolve the problem of stresses with existing layers when the level of the lattice mismatch is larger than 3%.

In order to have a complete and convenient manufacturing method for further resolving the stress problem, the present invention provides a new manufacturing method of a semiconductor device. The present invention utilizes general processes to implement this method. Unlike prior arts, it does not need an additional film or structure for improving the stress issue resulting from the lattice mismatch, so no additional films or structures are present to absorb the light emitted by an active layer and decrease the photo-electronic effect. In addition, the present invention provides a manufacturing method of a semiconductor device which is advantageous to the device in a sequential die-cutting process.

The present invention utilizes a patterned substrate previously made as a base for growing a Group III nitride semiconductor material or a photo-electronic device. In particular, when the Al composition of a grown Group III nitride semiconductor material (e.g. AlₗIn_{y}Ga_{1-x-y}N, x>0.25) is greater than 25%, the present invention can dramatically reduce the internal stress of the material to avoid the failure of the device due to cracks in the material. In addition, the stresses existing in the internal material are also reduced so the photo-electronic effect of the device is improved. Furthermore, the manufacturing method of a semiconductor device provided by the present invention eliminates the need for an additional structure in the device for reducing the accumulation of stresses, and the photo-electronic effect of the primary device is not degenerated by such additional structure.

The present invention provides a manufacturing method of a semiconductor device, which comprises the steps of: providing a substrate; forming a plurality of grooves on the substrate by photolithograph etching or laser engraving, wherein the plurality of grooves divides a surface of the substrate into a plurality of mesas and the substrate is a patterned substrate; and growing a semiconductor device (e.g. photo-electronic device or LED) on the patterned substrate. The semiconductor device comprises at least one layer, wherein the layer directly disposed on the patterned substrate is the first layer. The first layer comprises a plurality of separated regions divided by the grooves.

During the epitaxial process, if the lattice mismatch between two stacked layers is greater than 3%, the stresses occurring therein can easily cause cracks in the layers. The patterned substrate provided by the present invention can reduce the internal stresses of the first layer. The present invention is based on the following rules: an original first layer should have a large area, but the current first layer is divided by the aforesaid grooves into a plurality of small regions; the stresses existing in crowded lattices of the layer continuously pushing each other due to the lattice mismatch can be released through the grooves to avoid the cracks of the layer material; the quality of the device is therefore maintained at a high level.

The width of the aforesaid grooves is not less than 2 μm, and the depth of them is not less than 1 μm. The preferable depth ranges from 1 μm to 15 μm. Furthermore, the shape of the aforesaid single mesa is square, rhombus, circular, oval, parallelogram or irregular polygonal. The average diameter or the average circumference of the mesa ranges from 50 μm to 2 mm or is larger than 2 mm.

Furthermore, the material of the aforesaid patterned substrate is sapphire (Al₂O₃ with single crystal), and that of the first layer is Group III nitride semiconductor which can be AlₓIn_{y}Ga_{1-x-y}N, where 0≦x+y≦1. The manufacturing method of a semiconductor device provided by the present invention is well-suited to growing the material of AlₓIn_{y}Ga_{1-x-y}N, where x>0.25. In addition, the material of the aforesaid patterned substrate can also be SiC. In one embodiment, the material of the patterned substrate is sapphire, and the material of the first layer is GaN. The lattice mismatch of the sapphire and GaN is around 13.8%. The stresses can be released from the two layers by using the manufacturing method of a semiconductor device provided by the present invention.

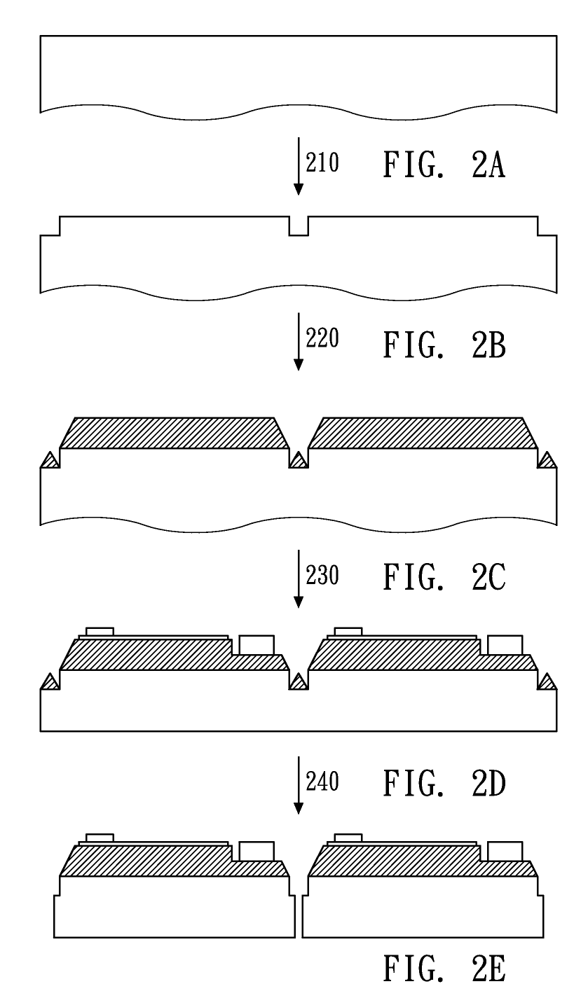

FIGS. 2A-2E illustrate the manufacturing processes of the semiconductor device in accordance with the present invention. Step 210 illustrates the formation process of a patterned substrate. That is, a plurality of grooves is formed on the surface of a substrate by photolithograph etching or laser engraving. In Step 220, a first layer and other Group III nitride semiconductor materials are formed on the patterned substrate. As shown in FIG. 2C, the layers (hatched area) grown on the patterned substrate are divided into a plurality of regions by the grooves. Step 230 illustrates the formation, after the semiconductor materials are formed, of a transparent conductive layer, P type electrodes and N type electrodes. Finally, Step 240 illustrates the cutting along the grooves to form a plurality of independent devices.

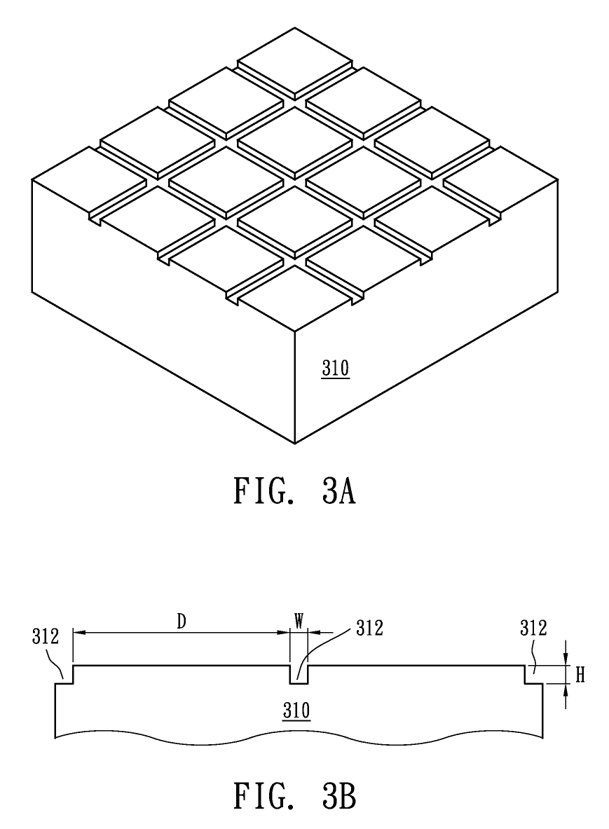

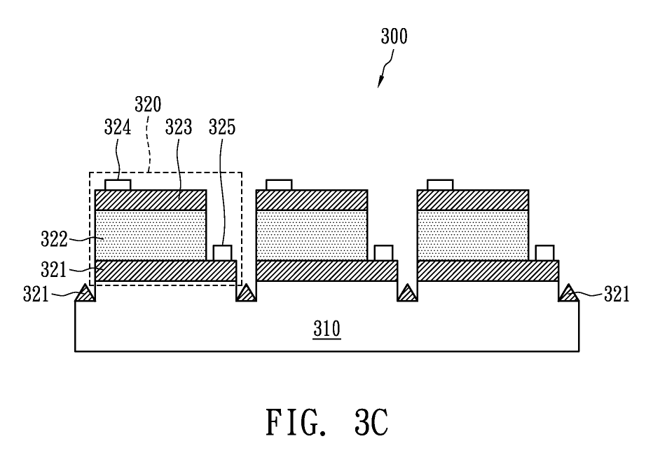

FIG. 3A is a solid diagram of the patterned substrate in accordance with the present invention, FIG. 3B is a cross section diagram of FIG. 3A, and FIG. 3C is a structure 300 of semiconductor devices in accordance with the present invention. It comprises a patterned substrate 310 having a plurality of grooves 312 and a plurality of semiconductor devices 320 disposed on the patterned substrate 310.

The surface of the patterned substrate 310 is divided by the grooves 312 into a plurality of mesas, as shown in FIG. 3A. The shape of the aforesaid single mesa is square, rhombus, circular, oval, parallelogram or irregular polygonal. The average diameter (referring to label D in FIG. 3B) or the average circumference of the mesa ranges from 50 μm to 2 mm or is larger than 2 mm. Furthermore, the width (referring to label W in FIG. 3B) of the aforesaid grooves 312 is not less than 2 μm, and the depth (referring to label H in FIG. 3B) of them is not less than 1 μm. The preferable depth ranges from 1 μm to 15 μm.

The semiconductor device 320 comprises at least one layer, wherein the layer directly disposed on the patterned substrate 310 is the first layer 321. The first layer 321 comprises a plurality of separated regions divided by the grooves 312. The stresses existing in lattices of the layer resulting from the lattice mismatch can be released through the grooves 312 to prevent lattices from continuously pushing each other to cause the cracks of the devices, and the quality of the device is maintained at a high level. Therefore, the patterned substrate provided by the present invention can reduce the internal stresses of the first layer. In addition, the plurality of grooves on the substrate is advantageous to the LED devices in terms of the sequential die-cutting process and the low manufacturing cost.

The aforesaid semiconductor device can be any of photo-electronic devices such as LEDs. The material of the aforesaid patterned substrate is Al₂O₃ (sapphire), and that of the first layer is Group III nitride semiconductor. The material of the Group III nitride semiconductor is AlₓIn_{y}Ga_{1-x-y}N, where x and y meet the inequality of 0≦x+y≦1. The manufacturing method of a semiconductor device provided by the present invention is well-suited to growing the material of AlₓIn_{y}Ga_{1-x-y}N, where x>0.25.

FIG. 3C shows the structure 300 of semiconductor devices provided by the present invention. In FIG. 3C, the semiconductor device 320 on the surface of the patterned substrate 310 further comprises a first layer 320 and other Group III nitride semiconductor materials 322, a transparent conductive layer 323, P type electrodes 324 and N type electrodes 325. The material of the transparent conductive layer 323 can be selected from the group consisting of ITO, IZO, ZnO, NiO, CTO and any mixture of the aforesaid compounds, and can be selected from the group consisting of ZnO:Al, ZnGa₂O₄, SnO₂:Sb, Ga₂O₃:Sn, AgInO₂:Sn, In₂O₃:Zn, CuAlO₂, LaCuOS, CuGaO₂, and SrCu₂O₂.

In addition, the material of the aforesaid patterned substrate can also be SiC. In one embodiment, the material of the patterned substrate is sapphire, and the material of the first layer is GaN. The lattice mismatch of the sapphire and GaN is around 13.8%. The stresses can be released from the two layers by using the manufacturing method of a semiconductor device provided by the present invention.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A manufacturing method of semiconductor device, comprising:
providing a substrate;
forming a plurality of grooves on the substrate to obtain a patterned substrate; and
growing a semiconductor device on the patterned substrate, the semiconductor device comprising at least one layer, wherein the at least one layer of the semiconductor device directly disposed on the patterned substrate is a first layer and the first layer comprises a plurality of separated regions divided by the grooves.

2. The manufacturing method of a semiconductor device of claim 1, wherein the width of the grooves is not less than 2 μm.

3. The manufacturing method of a semiconductor device of is claim 1, wherein the depth of the grooves is not less than 1 μm.

4. The manufacturing method of a semiconductor device of claim 3, wherein the depth of the grooves ranges from 1 μm to 15 μm.

5. The manufacturing method of a semiconductor device of claim 1, wherein the patterned substrate is formed by photolithograph etching or laser engraving.

6. The manufacturing method of a semiconductor device of claim 1, wherein the semiconductor device is a photo-electronic device.

7. The manufacturing method of a semiconductor device of claim 6, wherein the semiconductor device is an LED.

8. The manufacturing method of a semiconductor device of claim 1, wherein the material of the first layer is Group III nitride semiconductor.

9. The manufacturing method of a semiconductor device of claim 8, wherein the Group III nitride semiconductor is AlₓIn_{y}Ga_{1-x-y}N, where 0≦x+y≦1.

10. The manufacturing method of a semiconductor device of claim 1, wherein a surface of the patterned substrate is divided by the grooves into a plurality of mesas.

11. The manufacturing method of a semiconductor device of claim 10, wherein the shape of the mesa is square, rhombus, circular, oval, parallelogram or irregular polygonal.

12. The manufacturing method of a semiconductor device of claim 10, wherein the average diameter or the average circumference of the mesa ranges from 50 μm to 2 mm.

13. The manufacturing method of a semiconductor device of claim 1, wherein the material of the patterned substrate is sapphire which is Al₂O₃ with single crystal.

14. The manufacturing method of a semiconductor device of claim 1, wherein the patterned substrate reduces stresses in the first layer.

15. A structure of a semiconductor device, comprising:
a patterned substrate including a plurality of grooves; and
a semiconductor device on the patterned substrate, the semiconductor device comprising at least one layer, wherein the at least one layer of the semiconductor device directly disposed on the patterned substrate is a first layer and the first layer comprises a plurality of separated regions divided by the grooves.

16. The structure of a semiconductor device of claim 15, wherein the width of the grooves is not less than 2 μm.

17. The structure of a semiconductor device of claim 15, wherein the depth of the grooves is not less than 1 μm.

18. The structure of a semiconductor device of claim 17, wherein the depth of the grooves ranges from 1 μm to 15 μm.

19. The structure of a semiconductor device of claim 15, wherein the semiconductor device is a photo-electronic device.

20. The structure of a semiconductor device of claim 19, wherein the semiconductor device is an LED.

21. The structure of a semiconductor device of claim 15, wherein the material of the first layer is Group III nitride semiconductor.

22. The structure of a semiconductor device of claim 15, wherein the Group III nitride semiconductor is AlₓIn_{y}Ga_{1-x-y}N, where 0≦x+y≦1.

23. The structure of a semiconductor device of claim 15, wherein a surface of the patterned substrate is divided by the grooves into a plurality of mesas.

24. The structure of a semiconductor device of claim 23, wherein the shape of the mesa is square, rhombus, circular, oval, parallelogram or irregular polygonal.

25. The structure of a semiconductor device of claim 23, wherein the average diameter or the average circumference of the mesa ranges from 50 μm to 2 mm.

26. The structure of a semiconductor device of claim 15, wherein the material of the patterned substrate is sapphire which is Al₂O₃ with single crystal.

27. The structure of a semiconductor device of claim 15, wherein the patterned substrate reduces stresses in the first layer.
